(19) United States
(12) Patent Application Publication
(10) Pub. No.: US 2017/0059618 A1
(43) Pub. Date: Mar. 2, 2017

(54) WIRELESS OSCILLOSCOPE

(71) Applicant: Aeroscope Labs LLC, Boulder, CO (US)

(72) Inventors: Alexander L. LEE, Longmont, CO (US); Jonathan R. WARD, Boulder, CO (US)

(21) Appl. No.: 15/252,456

(22) Filed: Aug. 31, 2016

Related U.S. Application Data
(60) Provisional application No. 62/212,438, filed on Aug. 31, 2015.

(51) Int. Cl. G01R 13/02; G01R 31/36

(52) U.S. Cl. CPC G01R 13/0254; G01R 31/3682

(57) ABSTRACT

A wireless handheld oscilloscope includes a casing and oscilloscope circuitry within the casing. The wireless handheld oscilloscope processes an electronic signal and wireless transmits digital waveform data representative of the electronic signal for display on the electronic device. The wireless handheld oscilloscope optionally includes circuitry configured to transmit an external trigger signal to a second wireless oscilloscope to synchronize with the second wireless oscilloscope.

### CROSS-REFERENCE TO RELATED APPLICATIONS

This application claims the benefit of priority from U.S. Provisional Patent Application No. 62/212,438, filed Aug. 31, 2015, which is hereby incorporated by reference to the extent not inconsistent with the disclosure of this application.

### BACKGROUND

Oscilloscopes are commonly used for measuring signals in electrical circuits. Generally an oscilloscope couples to a probe having two leads. When in use, the two leads are connected to two parts of an electronic circuit. The oscilloscope displays a waveform indicating the voltage difference between the two parts of the electronic circuit vs time. In this way the oscilloscope can make an electrical measurement of an electronic circuit.

Traditional oscilloscopes are relatively large, stationary, and expensive devices. Typically, when measuring an electrical circuit the electrical circuit must be brought to the stationary oscilloscope for measurement. This can be very inconvenient when the electrical circuit is not easily brought to the stationary oscilloscope.

### SUMMARY

According to an embodiment, a wireless handheld oscilloscope includes a handheld oscilloscope casing, a probe connector coupled to the oscilloscope casing and configured to couple to a probe, and oscilloscope circuitry positioned within the handheld oscilloscope casing. The oscilloscope circuitry is configured to receive an electrical signal via the probe connector, to generate digital waveform data by processing the electrical signal, and to wirelessly transmit the digital waveform data to an electronic device for display by the electronic device. In certain embodiments, the oscilloscope circuitry is further configured to transmit an external trigger signal to a second wireless oscilloscope to synchronize with the second wireless oscilloscope.

According to an embodiment, a method includes receiving, with a handheld wireless oscilloscope, an electronic signal and generating digital waveform data representative of the electronic signal by processing the electronic signal with oscilloscope circuitry positioned within a casing of the handheld wireless oscilloscope. The method further includes wirelessly outputting the digital waveform data from the handheld wireless oscilloscope to an electronic device.

According to an embodiment, a system includes a wireless handheld oscilloscope and an electronic device. The wireless handheld oscilloscope includes an oscilloscope casing having a shape and size that promote being held in a hand of a user while the oscilloscope is in use and oscilloscope circuitry positioned within the housing and configured to measure an electrical signal and to wirelessly transmit digital waveform data representative of the electrical signal. The electronic device has a display and is configured to wirelessly communicate with the oscilloscope, to receive the digital waveform data and to display the digital waveform data on the display.

According to an embodiment, a wireless handheld oscilloscope includes a handheld oscilloscope casing, a probe connector coupled to the oscilloscope casing and configured to couple to a probe, and oscilloscope circuitry positioned within the handheld oscilloscope casing. The oscilloscope circuitry is configured to (a) receive an electrical signal via the probe connector, to generate digital waveform data by processing the electrical signal, (b) wirelessly transmit the digital waveform data to an electronic device for display by the electronic device, (c) determine that a trigger event has occurred by comparing the digital waveform data to a trigger threshold, (d) estimate an actual trigger time corresponding to an actual trigger event where the electrical signal crossed the trigger threshold, (e) determine a difference between (1) a time when the trigger event was determined to have occurred and (2) the actual trigger time, and (f) offset a time component of the digital waveform data by the difference, on a frame-by-frame basis, until a next determined trigger event.

In an embodiment, a method for compensating for trigger jitter in a digital oscilloscope includes (a) determining occurrence of a trigger event by comparing digital waveform data, representing an analog electrical signal, to a trigger threshold, (b) estimating an actual trigger time corresponding to an actual trigger event where the analog electrical signal crossed the trigger threshold, (c) determining a difference between (1) a time when the trigger event was determined to have occurred and (2) the actual trigger time, and (d) offsetting a time component of the digital waveform data by the difference, on a frame-by-frame basis, until a next determined trigger event.

### BRIEF DESCRIPTION OF THE DRAWINGS

FIG. 1 is a block diagram of a system including a handheld oscilloscope and an electronic device, according to an embodiment.

FIG. 2A-2E are diagrams of a wireless handheld oscilloscope, according to an embodiment.

FIG. 3 is a diagram of oscilloscope circuitry positioned within a wireless handheld oscilloscope, according to an embodiment.

FIG. 4 is a block diagram of a Field Programmable Gate Array of the oscilloscope circuitry, according to an embodiment.

FIG. 5 is a diagram of a system including a first and a second wireless oscilloscope and an electronic device, according to an embodiment.

FIG. 6 is a flow diagram of a method for operating a handheld oscilloscope, according to an embodiment.

FIG. 7 is a flow diagram of a method for compensating for trigger jitter, according to an embodiment.

### DETAILED DESCRIPTION OF THE EMBODIMENTS

In the following detailed description, reference is made to the accompanying drawings, which form a part hereof. In the drawings, similar symbols typically identify similar components, unless context dictates otherwise. Other embodiments may be used and/or other changes may be made without departing from the spirit or scope of the disclosure.

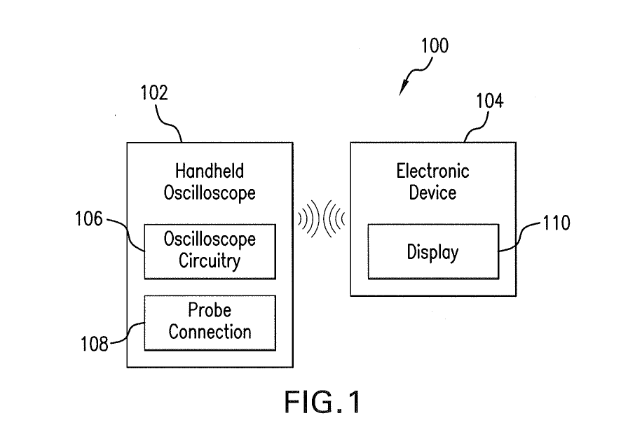

FIG. 1 is a block diagram of system 100 including a wireless handheld oscilloscope 102 and an electronic device 104, according to an embodiment. The wireless handheld oscilloscope 102 includes oscilloscope circuitry 106 and a probe connection 108. The electronic device 104 includes a display 110.

According to an embodiment, the wireless handheld oscilloscope 102 is a compact, portable wireless oscilloscope that can be handheld. The probe connection 108 is compatible to connect to a probe having two leads that can be coupled to selected areas of an electronic circuit for making measurements of the electronic circuit.

In operation, the oscilloscope circuitry 106 receives an electrical signal from the probe via the probe connection 108. The two probe leads can be connected to two different locations of the electronic circuit. The oscilloscope circuitry 106 processes the electrical signal, generates digital waveform data representing the electronic signal, and wirelessly transmits the digital waveform data to the electronic device 104. The electronic device 104 receives the digital waveform data from the wireless handheld oscilloscope 102 and displays the digital waveform data on the display 110. According to an embodiment, the digital waveform data indicates the voltage difference between the two parts of the electronic circuit vs time.

According to an embodiment, the wireless handheld oscilloscope 102 has a shape and size that allows a user to easily and comfortably hold the wireless handheld oscilloscope 102 in the user's hand. This gives great flexibility to the user of the wireless handheld oscilloscope 102 to conveniently take the wireless handheld oscilloscope 102 to any location to make measurements of an electronic circuit rather than having to take the electronic circuit to a workbench where a traditional non-handheld oscilloscope is located.

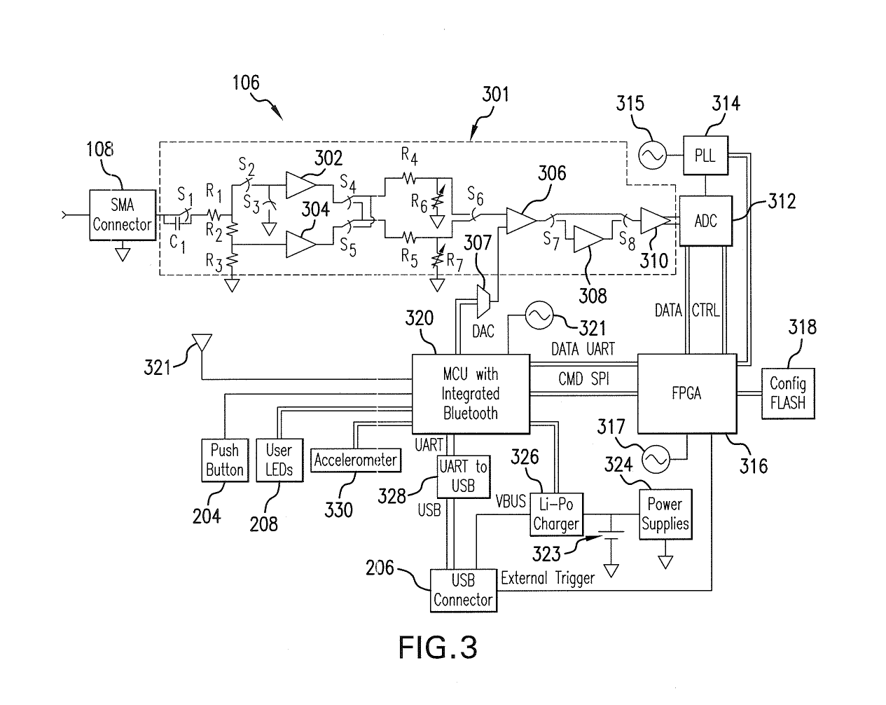

According to an embodiment, the wireless handheld oscilloscope 102 includes an internal battery (FIG. 3, 323) by which the oscilloscope circuitry 106 is powered. Thus, the handheld wireless oscilloscope 102 does not have a dedicated earth ground connection.

According to an embodiment, the electronic device 104 can be one of a smart phone, a tablet, a laptop, an MP3 player, a desktop computer, or another suitable device including wireless communication capabilities and the display 110. The electronic device 104 can include a software application that allows the electronic device 104 to communicate with the wireless handheld oscilloscope 102, to display oscilloscope measurements on the display 110, and to control operation of the handheld oscilloscope.

According to an embodiment, the probe connection 108 can be SubMiniature version A (SMA) connection configured to couple with a probe including an SMA cable. Additionally or alternatively, the SMA connection 108 can include any other suitable connection type for coupling with a probe. The probe can include attenuating probes, alligator clips, other suitable electrodes for coupling to an electronic circuit for making measurements, or current probes. In some embodiments, the probe includes a rigid probe tip to facilitate coupling to small circuitry.

In one example, if a technician needs to make electrical measurements of an electrical circuit within an airplane, the technician can conveniently take the wireless handheld oscilloscope 102 to whatever part of the airplane that the electronic circuit is located. The user can then connect a probe between the electrical circuit and the probe connection 108 of the wireless handheld oscilloscope 102. The oscilloscope circuitry 106 can then make electrical measurements of the electronic circuit and wirelessly transmit the electrical measurements in the form of digital waveform data to the user's cell phone, which functions as the electronic device 104. The cell phone displays the waveform on the screen. Thus, the user can easily and conveniently make oscilloscope measurements anywhere that the user can take his/her phone and the pen-sized wireless handheld oscilloscope 102.

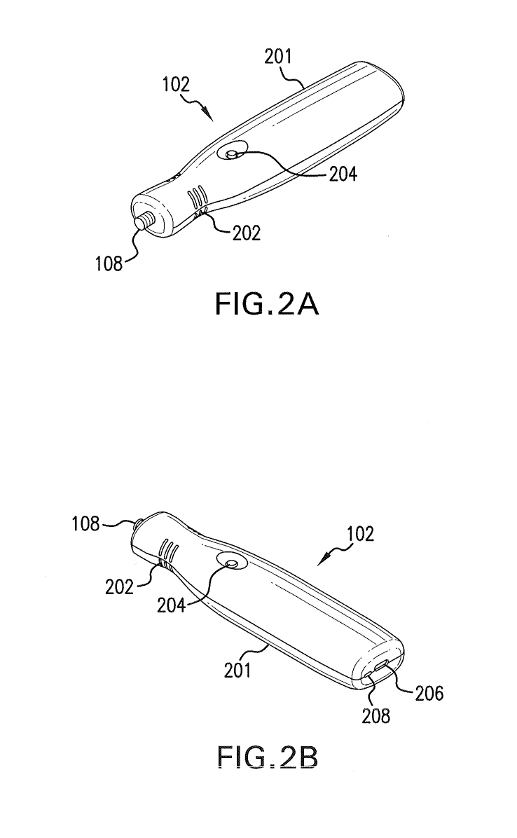

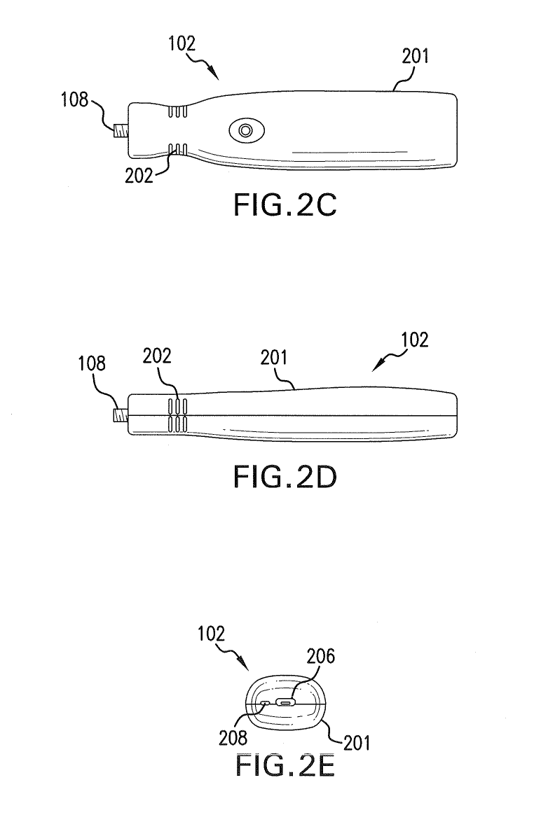

FIGS. 2A-2E illustrate various views of a wireless handheld oscilloscope 102, according to an embodiment. The wireless handheld oscilloscope 102 includes a casing 201 having approximately the size and shape of a pen, a probe connector 108, grips 202, a button 204, and a micro USB port 206. The oscilloscope circuitry 106 (not shown in FIGS. 2A-2E) is positioned within the casing 201. The size and shape of the oscilloscope casing 201 allow the wireless handheld oscilloscope 102 to be comfortably held in a user's hand to make electrical measurements of an electronic circuit.

FIG. 2A is a perspective view of the oscilloscope 102, according to an embodiment. The probe connector 108 is at a forward end of the oscilloscope casing 201. The probe connector 108 is configured to couple with a probe, for example an SMA probe. In particular, the SMA probe can be coupled to the probe connector 108 by screwing the SMA probe to the probe connector 108. The button 204 is positioned on the top face of the oscilloscope casing 201 and allows the user easy access to control features without having to move his/her hand.

The grips 202 can include grooves scored in the oscilloscope casing 201 that make the oscilloscope casing 201 easier to hold without slippage. Additionally or alternatively, the grips 202 can be configured to couple to a holder that fixes the oscilloscope casing 201 in a selected position.

FIG. 2B is a perspective view of the wireless handheld oscilloscope 102 more clearly displaying a rearward end of the oscilloscope casing 201, according to an embodiment. The micro USB port 206 and an LED indicator 208 are positioned at the rearward end of the oscilloscope casing 201.

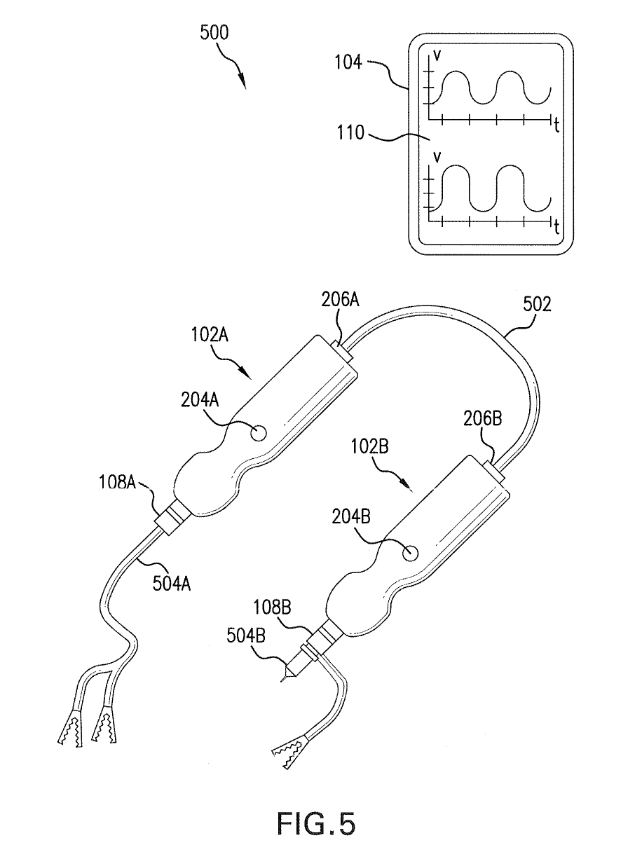

According to an embodiment, the micro USB port 206 can be used as a port to charge a battery of the wireless handheld oscilloscope 102. Alternatively or additionally, the micro USB port 206 can be used to connect, via a modified micro USB cable, two handheld oscilloscopes 102. In such a situation one wireless handheld oscilloscope 102 will act as a master to the other oscilloscope 102, which will act as a slave. In this configuration, two measurements can be made simultaneously and displayed on the display 110 of the electronic device 104 (shown in FIGS. 1 and 5). The master oscilloscope 102 can send an external trigger signal to the slave oscilloscope 102 via the USB cable. The external trigger signal syncs the master and the slave oscilloscopes. The master oscilloscope 102 wirelessly transmits digital waveform data to the electronic device 104, after which the slave oscilloscope transmits digital waveform data to the electronic device 104. The electronic device 104 can simultaneously display measurements from both handheld oscilloscopes 102.

The LED indicator 208 can indicate one or more of the charge level of the battery, whether the battery is currently being charged, whether the oscilloscope 102 is on or off, whether the oscilloscope 102 is in communication with the electronic device 104, or any other useful indications. The LED indicator 208 can include a single LED or multiple LEDs.

FIG. 2C is a top view of the oscilloscope 102, according to an embodiment. The top view shows the button 204 positioned on the top face of the oscilloscope 102, the grips 202 positioned near the front-end of the oscilloscope 102, and the SMA connector 108 positioned at the front-end of the oscilloscope 102.

FIG. 2D is a side view of the oscilloscope 102, according to an embodiment. The side view illustrates the relative thickness of the oscilloscope 102 as well as the grips 202 and the SMA connector 108.

FIG. 2E is a view of the rearward end of the oscilloscope 102, according to an embodiment. The view of FIG. 2E illustrates the micro USB port 206 and the LED indicator 208 positioned on the rear face of the oscilloscope housing 102.

FIG. 3 is a schematic diagram of the oscilloscope circuitry 106 positioned within the oscilloscope casing 201, according to an embodiment. The oscilloscope circuitry 106 receives an analog electronic signal from the SMA connector 108, conditions the analog signal, converts the analog electronic signal into digital waveform data, and wirelessly transmits the digital waveform data to the electronic device 104 for display. Thus, the oscilloscope circuitry 106 housed within the oscilloscope casing 201 receives an analog electronic signal, processes the analog electronic signal, and wirelessly outputs digital waveform data for display on the electronic device 104.

The oscilloscope circuitry 106 includes an analog front-end portion 301 that conditions the analog electronic signal for digitization. The analog front-end 301 receives the analog electronic signal from the SMA connector 108. According to an embodiment, the analog front-end 301 can filter the analog electronic signal, amplify the analog electronic signal, attenuate the analog electronic signal, and adjust a DC offset of the analog signal in preparation for converting the analog signal to digital waveform data.

According to an embodiment, the analog front end 301 includes a capacitor C1, switches S1-S8, resistors R1-R7, and amplifiers 302, 304, 306, 308, and 310. The analog electronic signal is passed from the SMA connector 108 to the switch S1 and the capacitor C1, connected together in parallel. The switch S1 can be opened or closed to place the oscilloscope 102 in a DC couple mode or an AC couple mode. In particular, when the switch S1 is closed the capacitor C1 is shorted and the oscilloscope 102 is placed in DC couple mode. When the switch S1 is opened the oscilloscope 102 is placed in AC couple mode and an AC analog signal is filtered through the capacitor C1. The user can place the oscilloscope in AC or DC couple mode by selecting AC or DC couple mode via the oscilloscope software application on the electronic device 104 (shown in FIGS. 1 and 5).

The analog electronic signal is then passed to an attenuation stage that can attenuate the analog electronic signal to a selected degree. The attenuation stage includes the resistors R1-R7, the switches S2-S6, and the amplifiers 302, 304.

The analog electronic signal is passed through the resistors R1-R3 to the two amplifiers 302, 304. The resistors R1-R3 act as a voltage divider that attenuates the analog electronic signal. The input of the amplifier 302 is connected between R1 and R2. The input of the amplifier 304 is connected between R2 and R3. The signal received by the amplifier 302 is attenuated to a lesser extent than the signal received by the amplifier 304. The amplifiers 302, 304 are configured as buffers having unity gain.

The switches S4, S5 selectively couple the outputs of the amplifier 302, 304 to a high attenuation path or to a low attenuation path. The high attenuation path includes the resistor R5 and a variable resistor R7. The low attenuation path includes the resistor R4 and a variable resistor R6. The variable resistors R6, R7 have resistances that can be adjusted to further fine tune the attenuation. Finally, the switch S6 selectively couples either the high attenuation path or the low attenuation path to an amplifier 306. Thus, resistors R1-R7, the switches S4-S6, and the amplifiers 302, 304 are configured to attenuate the analog signal in a variable manner and to pass an attenuated analog signal to the amplifier 306.

The amplifier 306 receives the attenuated analog signal from the attenuation stage and adjusts a DC offset to a selected value in conjunction with the digital-to-analog converter (DAC) 307, as described in more detail below. The amplifier 306 then passes the signal to an amplification stage.

The amplification stage includes the switches S7, S8 and the fixed gain amplifier 308. The switches S7, S8 can be operated to either pass the signal through the fixed gain amplifier 308 to a single ended differential output amplifier 310 or to bypass the fixed gain amplifier 308. The single ended differential output amplifier 310 receives the signal and outputs differential signals, centered around a selected DC offset, to the analog-to-digital converter (ADC) 312.

In the manner described above, the analog front-end 301 conditions the analog electronic signal in preparation for digitization of the analog electronic signal into waveform data that can be displayed on the display 110 of the electronic device 104. Thus, when the analog electronic signal is provided to the ADC 312 in differential form, the analog electronic signal has an amplitude, a DC offset, and a frequency that can readily be processed by the ADC 312.

According to an embodiment, the ADC 312 receives the analog differential signals from the amplifier 310, converts the differential signal to digital waveform data representative of the analog electrical signal. The ADC 312 digitizes the analog electronic signal relative to an internal reference voltage. The ADC 312 samples the differential signals at a sample rate set by a phase locked loop (PLL) 314. The PLL 314 receives a clock signal from a clock 315 and outputs a phase locked clock signal to the ADC 312, thereby setting the sample rate of the ADC 312. The sample rate of the ADC 312 can be adjusted by the user via the software application installed on the electronic device 104.

The ADC 312 outputs the digital waveform data on a DATA line to a Field Programmable Gate Array (FPGA) 316. The FPGA 316 stores the digital waveform data in the internal RAM block. The FPGA 316 sends control signals to the ADC 312 and the PLL 314. The FPGA 316 receives a clock signal from a clock 317. The FPGA 316 outputs the digital waveform data to a microcontroller 320 integrated with Bluetooth capability.

According to an embodiment, the FPGA 316 outputs the digital waveform data in frames to be successively displayed on the display 110 of the electronic device 104. Thus, according to an embodiment, the digital waveform data can constitute a video signal transmitted from the handheld oscilloscope to the electronic device 104.

In some circumstances, a user may wish to see when the signal crosses a particular voltage value. For investigating these signals, some reference point in time needs to be set to define when to start drawing the waveform on the screen. This reference point is set by a trigger module of the FPGA 316. The trigger module is used to define a trigger event from the measured signal. Measured signal data is captured and stored in the memory of the FPGA 316 relative to the timing of the trigger event. Data can be captured for some period of time before the trigger event, some period of time after a trigger event, or a combination of both. The user sets a voltage threshold for the trigger event on the electronic device 104. This voltage threshold is converted into an ADC count and stored in a register in the FPGA 316. The trigger event occurs when the measured signal crosses the trigger threshold. This behavior is also defined by the user through the trigger slope control. The trigger can be activated when the measured ADC count rises from below the trigger threshold to above, falls from above the threshold to below, or any crossing either rising or falling of the trigger threshold.

Each measured sample from the ADC 312 will be compared to previous measured samples to determine if a trigger event has occurred. To reduce the chance of false triggers caused by noise on the signal, trigger hysteresis can be adjusted and a low pass filter can be included.

Prior to a trigger event the data is stored in a ring buffer in the RAM block of the FPGA 316. The size of this ring buffer is dependent upon where in time, relative to the trigger event, the data that is displayed on the screen 110 comes from. If more pre-trigger data is desired, the ring buffer will be larger, conversely if more post trigger data is desired the ring buffer will be smaller. After a trigger event occurs, the remainder of the RAM block outside of the ring buffer will be filled with measured data. The user can set the trigger delay on the electronic device 104 and it will be written to a register in the FPGA 316. Once the memory is full, a memory control module reads the data back and sends it to the microcontroller 320 to be transmitted to the electronic device 104. According to an embodiment, the memory is read in order of oldest data to newest data, also known as first in first out (FIFO).

According to an embodiment, the user may also enable auto trigger mode. This mode is identical to normal trigger mode with the addition of a trigger timeout. If no trigger event is detected in a certain time window a trigger is generated anyway. This allows users to get a sense of viewing the signal in real time whether or not a trigger event has occurred. It is important to note that if trigger events do occur within the timeout window there is no difference between this mode and normal trigger mode.

According to an embodiment, a further trigger mode, roll mode, can also be selected by the user. Roll mode is typically used to look at slow moving signals such as sensor outputs (EKG signals, temperature sensors, etc.). In roll mode, the oscilloscope circuitry 106 is triggered to take a certain number of successive samples in a time period. Every sample captured by the ADC 312 is immediately sent on to the electronic device 104. The electronic device 104 graphs the waveform as it builds up “live” without waiting for a full frame to be captured.

The wireless handheld oscilloscope 102 may also be triggered externally. External triggering allows the user to sync two wireless oscilloscopes 102 and measure two signals simultaneously. A custom USB cable includes micro USB connectors on each end. The cable also includes a connection between each connector's ID pins. On standard USB cables the ID pin is not connected through the USB cable. This ID pin connection is used to carry a bidirectional trigger signal to trigger a second wireless oscilloscope 102 or receive a trigger signal from the wireless handheld oscilloscopes 102. The master probe and slave probe will be chosen through the application on the electronic device 104. When the master probe generates a trigger event it will also trigger the slave probe. The capture memory from the master probe will then be wirelessly transmitted to the electronic device 104, followed by the capture memory from the slave probe. The data for both devices will be displayed simultaneously on the electronic device. The length and dielectric properties of the custom USB cable are determined, for example, according to USB specifications known in the art. The slave probe accounts for expected propagation delay experienced by the trigger signal by offsetting the received trigger time by the expected propagation delay.

The microcontroller 320 receives the digital data from the FPGA and outputs the data via a Bluetooth antenna 321 to the electronic device 104. The electronic device 104 receives the digital data and displays the data on the display 110.

The microcontroller 320 is coupled to the USB port 206 via the Universal Asynchronous Receiver/Transmitter (UART) 328. The microcontroller 320 controls the charging of the lithium polymer battery 323 by controlling the Li—Po charger 326. In particular, when a charging cord is connected to the USB port 206, the microcontroller 320 controls the charger 326 to allow the charging of the battery 323. Supply voltages, such as VDD and ground, for the oscilloscope circuitry 106 are generated from the battery 323 by the power supply 324.

The microcontroller 320 is also connected to the button 204, the LED indicator 208, and an accelerometer 330. The button 204 can be used to start and stop data acquisition, force the wireless oscilloscope 102 into a low power state (sleep mode), or wake the probe up from sleep mode. According to an embodiment, the LED indicator 208 includes one or more LEDs positioned on or near the button 204 and/or one or more LEDs positioned near the USB port 206. The color of the LED associated with the push button 204 can correspond to the color of the data trace being displayed on the electronic device 104. The LED associated with the USB port 206 can indicate battery state and system power on state. In one example, the LED associated with the USB port 206 can periodically blink green when the oscilloscope is awake and the battery level is high. The LED can blink amber when the oscilloscope is awake and the battery level is mid level. The LED can blink red when the probe is awake and the battery level is low. The LED can be off when the probe is in sleep mode. Those of skill in the art will recognize that many other LED colors and indicating schemes can be used in accordance with principles of the present disclosure.

The accelerometer 330 senses motion of the oscilloscope 102. The microcontroller 320 can pause or resume operations of the oscilloscope circuitry 106 based on signals received from the accelerometer 330. For example, if the accelerometer 330 indicates that no movement has occurred for a selected period of time, then the microcontroller 320 can cause the oscilloscope circuitry 106 to enter a sleep mode or to turn off entirely in order to preserve the battery 323. Likewise, the microcontroller 320 can cause the oscilloscope circuitry 106 to resume operations when the signal from the accelerometer 330 indicates that the oscilloscope 102 has been moved.

The microcontroller 320 communicates with the electronic device 104 via the antenna 321. In particular, the microcontroller 320 transmits the waveform data to the electronic device 104 via the antenna 321. The microcontroller 320 receives information and commands from the electronic device 104 via the antenna 321. The antenna 321 can include one or more individual RF or IR antennas for communicating with a large variety of devices.

The microcontroller 320 also controls the DAC 307 to adjust a DC offset in the input analog signal in conjunction with the amplifier 306. In particular, if the input analog signal has a DC offset that is outside the range of the ADC 312, the microcontroller 320 causes the DAC 307 to output a signal to the amplifier 306 that adjusts the DC offset at the output of the amplifier 306. In this way the microcontroller 320, together with the DAC 307 and the amplifier 306, can adjust the DC offset of the input analog signal to a value that allows the ADC 312 to process the analog signal correctly.

According to an embodiment, the microcontroller 320 detects the presence of a DC offset by entering a calibration mode. In particular, the microcontroller 320 can control the switches S2, S3 to enter the calibration mode to detect if a DC offset is present in the input analog signal. In the calibration mode, the switch S3 is closed and the switch S2 is opened so that the input of the amplifier 302 receives ground voltage. During calibration, the microcontroller 320 can detect the presence and value of the DC offset and can cause the DAC 307 to adjust the offset.

According to an embodiment, the wireless oscilloscope 102 is uniquely discoverable as a wireless oscilloscope probe by advertising the presence of the oscilloscope service with a 128 bit Universally Unique Identifier (UUID). Any Bluetooth LE (BTLE) enabled electronic device 104 with corresponding software application that sees this service and UUID being advertised is able to make use of the functions provided by the wireless oscilloscope 102.

Voltage trace and control data is transferred to and from the wireless oscilloscope 102 via the characteristics that make up the wireless oscilloscope service. A characteristic is a variable size (20 byte maximum) register that can be written to or read from. The BTLE protocol takes care of the wireless transmission of the characteristic data to and from the wireless oscilloscope 102. To send trace data to the electronic device 104, the wireless oscilloscope 102 continuously updates its trace characteristic along with handshaking signals to signify the start and end of a capture frame.

According to an embodiment, the wireless oscilloscope 102 compresses the sampled data in such a way that allows higher data transfer rates than conventional BTLE enabled systems. Many BTLE implementations on commonly available smart devices severely limit the data rate of BTLE radio to improve battery life. Given a fixed data rate constraint of a channel, the only way to send more data over that channel is to compress the data. According to an embodiment, the wireless oscilloscope 102 implements a compression scheme based on Delta Huffman encoding to send more capture frames under the data rate constraints. Ordinarily, each sample is comprised of 8 bits. With Delta Huffman encoding, the size of each sample is determined by how different it is from the previous sample. It is statistically likely that a given sample will be close in value to the previous sample. Because of this, samples that are close in value to the prior sample are encoded using less than 8 bits. Samples far away in value may take more than 8 bits. A full 8 bit sample is sent to start the frame and each sample thereafter is encoded as the delta of the previous sample.

According to an embodiment, jitter and latency are reduced because all of the timing critical signals are in the wireless handheld oscilloscope itself. The communication latency will only affect the user interface (i.e. the video signal of the data to the electronic device 104 and how quickly a setting that is changed on the electronic device 104 is received by the wireless oscilloscope 102). The latency is small enough that it will not be perceptible to the user.

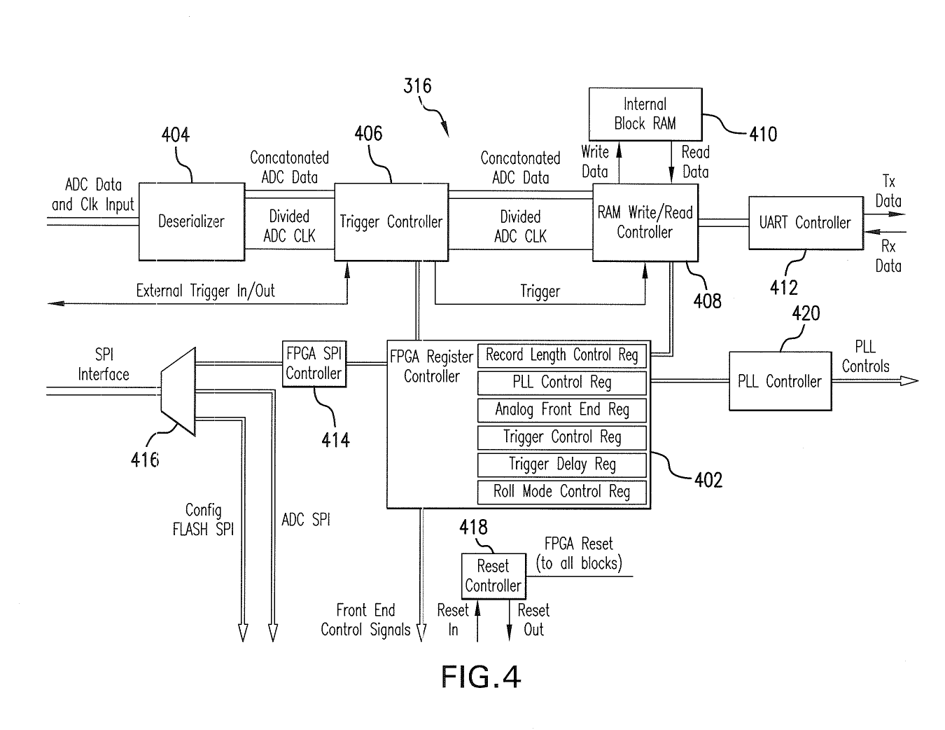

FIG. 4 is a block diagram of the FPGA 316, according to an embodiment. The FPGA 316 includes a register controller 402 that controls registry values. The register controller 402 includes Record Length Control Reg, PLL Control Reg, Analog Front-End Reg, Trigger Control Reg, Trigger Delay Reg, and Roll Mode Control Reg. The Record Length Control Reg can control the length of time that the waveform will represent. The PLL Control Reg can control the sample rate to be set by the PLL 314 (shown in FIG. 3). The Analog Front-End Reg can control the DC offset adjustment and whether calibration mode will be entered. The Trigger Control Reg can control the threshold for a trigger event. The Trigger Delay Reg can control the length of time before and after the trigger event that will be displayed. The Roll Mode Control Reg controls whether Roll Mode is entered.

The deserializer 404 receives the digital waveform data from the ADC 312 as well as a clock input and deserializes and concatenates the digital waveform data. The deserializer 404 passes the concatenated data, as well as a divided clock signal to a trigger controller 406.

The trigger controller 406 is controlled by the registry values in the FPGA register controller 402. The trigger controller 406 also receives or outputs the external trigger depending on the master/slave status of the oscilloscope 102 when two oscilloscopes are linked by the USB cable as described in relation to FIGS. 3, 5. The trigger controller 406 outputs the trigger value, the concatenated digital waveform data, and the divided clock signal to a RAM Write/Read Controller 408.

The RAM Write/Read Controller 408 writes the digital waveform data to an Internal Block RAM 410. The RAM Write/Read Controller 408 reads digital waveform data from the Internal Block RAM 410 and outputs the digital waveform data to the UART controller 412, which provides the digital waveform data to the microcontroller 320. The registry values in the register controller 402 control how much of the waveform pre and post trigger will be displayed.

A Serial Peripheral Interface (SPI) controller 414 controls an SPI Bus via a multiplexer 416 coupled to an SPI interface. A reset controller 418 controls the reset of the FPGA 316. All blocks of the FPGA 316 can be reset via the reset controller 418. The PLL controller 420 controls the ADC sample rate set by the PLL.

FIG. 5 is an illustration of a system 500 including a first pen-shaped wireless handheld oscilloscope 102a, a second pen-shaped wireless handheld oscilloscope 102b, and an electronic device 104, according to an embodiment.

The first and second wireless oscilloscopes 102a, 102b operate in a substantially similar manner as described with relation to FIGS. 1-3. The first wireless oscilloscope 102a is coupled to the second wireless oscilloscope 102b by a connector 502 coupled between USB connector ports 206a, 206b. Each of the wireless oscilloscopes 102a, 102b have probes 504a, 504b coupled to respective probe connector ports 108a, 108b. Probe 504A has two flexible leads terminating with respective alligator clips, and probe 504B has a rigid tip and one flexible lead terminating with an alligator clip. However, the configuration of probes 504A and 504B may be varied without departing from the scope hereof. For example, probe 504A could be modified to have a configuration like that of probe 504B, or probe 504B could be modified to have a configuration like that of probe 504A.

The first and second wireless oscilloscopes 102a, 102b each receive a respective electronic signal via the probes 504a, 504b and generate respective digital waveform data from the electronic signals. The first wireless oscilloscope 102a is a master to the second wireless oscilloscope 102b. The first wireless oscilloscope 102a sends external trigger data to the second wireless oscilloscope 102b to synchronize the first and second wireless oscilloscopes 102a, 102b. The master oscilloscope 102a wirelessly transmits digital waveform data to the electronic device 104, after which the slave oscilloscope 102b transmits digital waveform data to the electronic device 104. The electronic device 104 receives the digital waveform data from both the master and slave oscilloscopes 102a, 102b, and displays them both on the display 110.

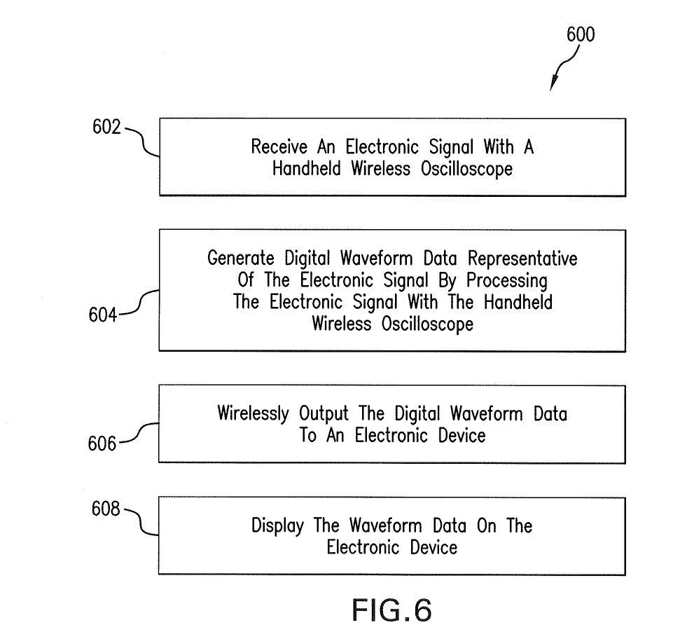

FIG. 6 is a flow diagram of a method 600 for operating a wireless handheld oscilloscope, according to an embodiment. At 602 a wireless handheld oscilloscope receives an electronic signal. The electronic signal is provided to the wireless handheld oscilloscope via a probe. The probe receives the electronic signal from electronic circuits under measurement. At 604, the wireless handheld oscilloscope generates digital waveform data representative of the electronic signal by processing the electronic signal. The wireless handheld oscilloscope processes the electronic signal with oscilloscope circuitry contained within the wireless handheld oscilloscope. At 606, the wireless handheld oscilloscope wirelessly outputs the digital waveform data to an electronic device. The electronic device is, for example, one of a smart phone, a laptop, a tablet, or a desktop computer. At 608, the electronic device displays the digital waveform data on a display of the electronic device. In this way, a user of the wireless handheld oscilloscope can make measurements of an electronic circuit with a wireless handheld oscilloscope and can display the measurement's waveform data on the electronic device, according to one embodiment.

Returning to FIG. 3, the phase relationship between clock 315 and the analog electronic signal from probe connection 108 is random and unknown. Consequently, measured samples of the digital waveform data from ADC 312 are not necessarily aligned in time relative to the digital waveform data from one video frame to another. Such misalignment causes trigger jitter when determining occurrence of a trigger event from the measured samples. Trigger jitter may be especially pronounced when viewing waveforms with fast rising edges, since magnitude of the analog electronic signal rapidly changes between successive measured samples of the digital waveform data.

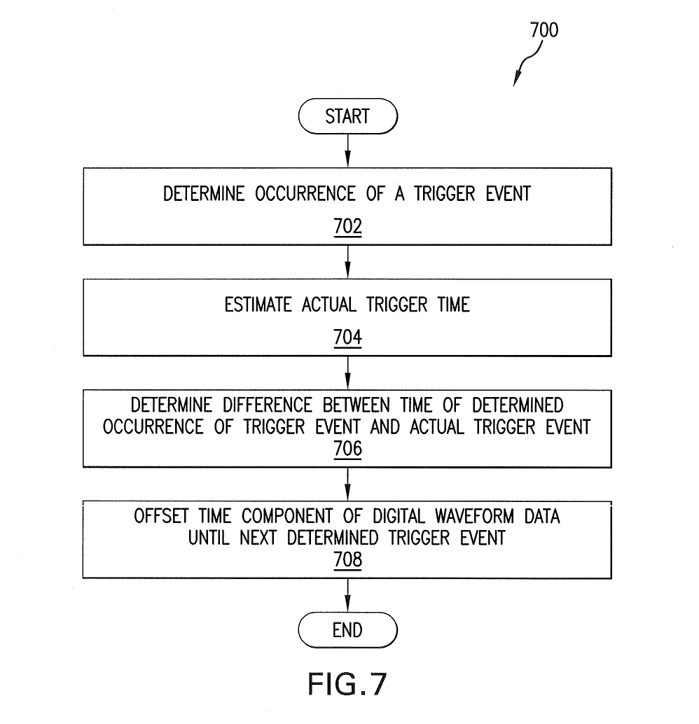

FPGA 316 is optionally further configured to at least partially compensate for trigger jitter by estimating actual trigger time after each determined trigger event, and offsetting a time component of the digital waveform data to compensate for a difference between (a) a time when the trigger event was determined to have occurred and (b) an actual trigger time. For example, certain embodiments perform a method 700, illustrated in FIG. 7, for compensating for trigger jitter. Method 700 begins with a step 702 of determining occurrence of a trigger event. In one example of step 702, trigger controller 406 of FPGA 316 determines that a trigger event has occurred by comparing digital waveform data from ADC 312 to a trigger threshold of 2.00 volts, and detecting at time t₁ that the digital waveform data has a magnitude greater than 2.00 volts, such as 2.03 volts.

In step 704, an actual trigger time, i.e., the time when magnitude of the analog electronic signal crossed the trigger threshold, is estimated. Actual trigger time will often be different from the time when the trigger event is determined to have occurred because the trigger event is determined by comparing digital waveform data representing the analog electronic signal, instead of the analog electronic signal itself, to the trigger threshold. In one example of step 704, trigger controller 406 of FGPA 316 estimates that the analog electronic signal rose above 2.00 volts at time t₀, which is before time t₁, using linear interpolation based on (a) a first measured sample of the digital waveform data corresponding to a time before t₁, (b) a second measured sample of the digital waveform data correspond to time t₁, and (c) the trigger threshold. In step 706, a difference between (a) a time when the trigger event was determined to have occurred and (b) the actual trigger time is determined. In one example of step 706, trigger controller 406 of FGPA 316 calculates a difference Δt equal to a difference between t₁ and t₀. In step 708, a time component of the digital waveform data is offset by the difference determined in step 706 on a frame-by-frame basis, until a next determined trigger event. In one example of step 708, FGPA 316 offsets a time component of digital waveform data from ADC 312 in the “positive” direction, that is, by advancing the time corresponding to each measured sample by Δt, on a frame-by-frame basis, until the next determined trigger event. Method 700 repeats upon the next determined trigger event.

While various aspects and embodiments have been disclosed herein, other aspects and embodiments are contemplated. The various aspects and embodiments disclosed herein are for purposes of illustration and are not intended to be limiting. The following claims are intended to cover generic and specific features described herein, as well as all statements of the scope of the present oscilloscopes, systems, and methods, which as a matter of language, might be said to fall there between.

What is claimed is:

1. A wireless handheld oscilloscope, comprising:
a handheld oscilloscope casing;
a probe connector coupled to the oscilloscope casing and configured to couple to a probe; and
oscilloscope circuitry disposed within the handheld oscilloscope casing and configured to:
receive an electrical signal via the probe connector, to generate digital waveform data by processing the electrical signal,
wirelessly transmit the digital waveform data to an electronic device for display by the electronic device, and
transmit an external trigger signal to a second wireless oscilloscope to synchronize with the second wireless oscilloscope.

2. The wireless handheld oscilloscope of claim 1, wherein the oscilloscope casing is substantially pen-shaped.

3. The wireless handheld oscilloscope of claim 1, the oscilloscope circuitry including:
an analog front-end portion coupled to the probe connector, the analog front-end portion including:
one or more signal attenuation circuit paths,
a signal amplifier configured to amplify the electrical signal, and
a DC-offset adjustment portion configured to adjust a DC-offset of the electrical signal;
an analog-to-digital converter (ADC) configured to receive the electrical signal from the analog front-end portion and to output the digital waveform data; and
a phase-locked loop configured to provide a clock signal to the ADC.

4. The wireless handheld oscilloscope of claim 3, the oscilloscope circuitry further including:
a Field Programmable Gate Array (FPGA) coupled to the ADC, the FPGA configured to receive the digital waveform data from the ADC and stores it in a memory of the FPGA; and
a microcontroller coupled to the ADC and the phase-locked loop, the microcontroller configured to receive the digital waveform data from the FPGA.

5. The wireless handheld oscilloscope of claim 4, wherein the microcontroller includes Bluetooth functionality, and the microcontroller is configured to wirelessly transmit the digital waveform data to the electronic device via Bluetooth protocol.

6. The wireless handheld oscilloscope of claim 4, wherein the oscilloscope circuitry further includes an accelerometer coupled to the microcontroller and configured to output a motion signal indicative of a motion of the oscilloscope casing.

7. The wireless handheld oscilloscope of claim 6, wherein the microcontroller is configured to enter or exit a sleep mode based on the motion signal.

8. The wireless handheld oscilloscope of claim 4, wherein the microcontroller is configured to receive user commands wirelessly from the electronic device and to execute the user commands.

9. The wireless handheld oscilloscope of claim 4, comprising one or more LEDs coupled to the microcontroller, the one or more LEDs configured to indicate one or more of an operational state of the wireless oscilloscope and a state of a battery of the wireless handheld oscilloscope.

10. The wireless handheld oscilloscope of claim 4, wherein the FPGA is configured to compress the digital waveform data.

11. The wireless handheld oscilloscope of claim 10, wherein the FPGA is configured to compress the digital waveform data according to Delta Huffman encoding.

12. The wireless handheld oscilloscope of claim 1, further comprising:
a battery positioned within the oscilloscope casing and configured to power the oscilloscope circuitry;
a USB connector port configured to receive a USB cable, wherein:
the battery is configured to be charged via the USB connector port, and
the oscilloscope circuitry is configured to connect with the second wireless oscilloscope via the USB connector port.

13. A system comprising:
the wireless handheld oscilloscope of claim 1; and
an electronic device having a display and being configured to wirelessly communicate with the oscilloscope, to receive the digital waveform data and to display the digital waveform data on the display.

14. The system of claim 13, wherein the electronic device includes a software application that, when executed, enables the electronic device to communicate with the oscilloscope and to display the digital waveform data, the electronic device being selected from the group consisting of a smart phone, a laptop, a tablet, and a desktop computer.

15. A wireless handheld oscilloscope, comprising:
a handheld oscilloscope casing;
a probe connector coupled to the oscilloscope casing and configured to couple to a probe; and
oscilloscope circuitry disposed within the handheld oscilloscope casing and configured to:
receive an electrical signal via the probe connector, to generate digital waveform data by processing the electrical signal,
wirelessly transmit the digital waveform data to an electronic device for display by the electronic device,
determine that a trigger event has occurred by comparing the digital waveform data to a trigger threshold,
estimate an actual trigger time corresponding to an actual trigger event where the electrical signal crossed the trigger threshold,
determine a difference between (a) a time when the trigger event was determined to have occurred and (b) the actual trigger time, and
offsetting a time component of the digital waveform data by the difference, on a frame-by-frame basis, until a next determined trigger event.

16. The wireless handheld oscilloscope of claim 15, wherein the oscilloscope casing is substantially pen-shaped.

17. The wireless handheld oscilloscope of claim 15, the oscilloscope circuitry including:
an analog front-end portion coupled to the probe connector, the analog front-end portion including:
one or more signal attenuation circuit paths,
a signal amplifier configured to amplify the electrical signal, and
a DC-offset adjustment portion configured to adjust a DC-offset of the electrical signal,
an analog-to-digital converter (ADC) configured to receive the electrical signal from the analog front-end portion and to output the digital waveform data; and
a phase-locked loop configured to provide a clock signal to the ADC.

18. The wireless handheld oscilloscope of claim 17, the oscilloscope circuitry further including:
a Field Programmable Gate Array (FPGA) coupled to the ADC, the FPGA configured to receive the digital waveform data from the ADC and stores it in a memory of the FPGA; and
a microcontroller coupled to the ADC and the phase-locked loop, the microcontroller configured to receive the digital waveform data from the FPGA.

19. A method for compensating for trigger jitter in a digital oscilloscope, comprising:
determining occurrence of a trigger event by comparing digital waveform data, representing an analog electrical signal, to a trigger threshold;
estimating an actual trigger time corresponding to an actual trigger event where the analog electrical signal crossed the trigger threshold;
determining a difference between (a) a time when the trigger event was determined to have occurred and (b) the actual trigger time; and
offsetting a time component of the digital waveform data by the difference, on a frame-by-frame basis, until a next determined trigger event.

20. The method of claim 19, the step of estimating comprising using linear interpolation to estimate the actual trigger time from (a) a first measured sample of the digital waveform data corresponding to a time before when the trigger event was determined to have occurred, (b) a second measured sample of the digital waveform data corresponding to the time when the trigger event was determined to have occurred, and (c) the trigger threshold.
